(19) United States
(12) Patent Application Publication
(10) Pub. No.: US 2002/0077763 A1
(43) Pub. Date: Jun. 20, 2002

(54) Automatic tester having separate coarse and precise timing modules

(76) Inventors: Edward C.M. Chang, San Francisco, CA (US); Derek S. Chang, San Francisco, CA (US); Deirdre McGlashan, San Francisco, CA (US)

Correspondence Address: Supreme Patent Services, Post Office Box 3318, Saratoga, CA, 95070, US

(21) Appl. No.: 09/745,284

(22) Filed: Dec. 20, 2000

(51) Int. Cl. G06F 19/00; G01R 27/28

(52) U.S. Cl. 702/120; 702/117

(57) ABSTRACT

An automatic tester uses a coarse timing subsystem and a formatter circuit to generate a first formatted waveform with coarse timing based on the information stored in a vector memory subsystem. The first formatted waveform is refined by a timing refiner circuit to form a second formatted waveform with precise timing. The timing refiner circuit includes a flip-flop device to re-synchronize and remove jitter in the first formatted waveform. A counter and/or shift register and vernier circuit in the timing refiner circuit then triggers the leading and trailing edges of the second formatted waveform with precise timing. The formatter circuit may be eliminated by using control signals of the memory devices in the vector memory subsystem to manipulate timing. The coarse timing subsystem may further be eliminated by providing sufficient range for the counters in the timing refiner circuit.

### FIELD OF THE INVENTION

The present invention relates generally to the architecture of an automatic test equipment (ATE), and more specifically to the timing generator and formatter circuits of an ATE system.

### BACKGROUND OF THE INVENTION

In the industry of integrated circuit manufacturing, an ATE system is used to test the functionality of an integrated circuit device. Most of today's ATE systems consist of five major subsystems as shown in FIG. 1. Although each subsystem may have different capablilities which vary from manufacturer to manufacturer, the system basically comprises a vector memory subsystem 101, a timing subsystem 102, a format and response subsystem 103, a deskew circuit 104 and a test head subsystem 105.

The vector memory subsystem 101 stores the information used for stimulating and testing a device and comparing with test results. The timing subsystem 102 determines the precise timing to input the information and compare the output of the device. The format and response subsystem 103 combines the data from the vector memory 101 with the precise timing to form a waveform and send it to the device. It also strobes the device output at precise timing and checks with the data from the vector memory 101 to determine if the device outputs the correct data. The deskew circuit 104 aligns all the channels within a few hundredths of a nanosecond at the device under test. Each pin of the device is physically connected to a channel. The test head subsystem 105 is the interface mechanism which connects each channel to each pin of the device.

In order to test a device, information that comes from the vector memory is driven into the device with precise timing as specified by the device's specification. After driving information into the device, the output of the device is sensed with precise timing and compared with the data in the vector memory to determine whether the device performs properly at a certain speed.

An ATE system consists of many channels (or pins). The number of pins can exceed more than one thousand. A tester's pin count must exceed the target device's pin count so a high end ATE system must have enough channels to support the latest devices. Since an ATE system is a general purpose test system, it is normally sold in terms of testing capability by incremental blocks of channels up to its maximum configuration as it is designed.

Each channel, in general, consumes at least 4 bits of memory data. One bit of data is used for the input waveform to the device with one timing generator associated with it. One bit of data is used with another timing generator to determine the time that the device is taking data rather than outputting data. These data are normally referred to as I/O (Input/Output data). One bit of data is used with the 3rd timing generator to check at the precise timing if the device is outputting correct information at the correct time. The 4th bit of data is used to ignore the device output if the device is at an unknown state. The 4th bit has no timing associated with it. It ignores the device output for the entire cycle. Therefore, three timing generators are used for each channel.

A timing generator includes two timing markers. One determines the leading edge of the timing signal, and the other determines the trailing edge. A conventional timing marker consists of a synchronous counter 201 and a vernier circuit 202 as shown in FIG. 2. The synchronous counter 201 counts up or down synchronously to its programmed value based on a system clock. It normally has 10 to 14 bits. The counter is initialized to its programmed value at the beginning of a cycle (period) by an initialize signal sent to the counter.

Because the resolution of the counter is based on the system clock, it does not provide enough resolution to be used for timing generators. Therefore, the output of the counter is fed into a vernier circuit 202 which can provide much finer resolution than the clock. A vernier circuit 202 is a programmable delay line or other form of analog circuit to produce finer resolution of time in picoseconds. The output of the vernier circuit 202 becomes a timing marker. The vernier circuit output is no longer synchronous to the system clock. FIG. 3 illustrates the timing diagram for a leading edge timing marker shown in FIG. 2.

Each timing generator is to generate an output in a range from the current cycle to the end of the second cycle. However, the counter is initialized at the beginning of each cycle. Therefore, before the counter counts up to its maximum value, it is initialized again. In order for the timing markers to have a programmable range from the current cycle (period) to the end of the next cycle, it is necessary to have two counters to count every other cycle as shown in FIG. 4. A conventional timing subsystem has two counters 401, 402 and a vernier circuit 403 in a marker illustrated in FIG. 4. The outputs of both counters are fed into the vernier circuit to achieve finer resolution than that of the system clock.

FIG. 5 shows the timing diagram of the timing marker shown in FIG. 4. The periods (cycles) in the timing subsystem are split into even and odd. The even counter 401 starts by the even parallel load signal and counts from the beginning of a current period to the end of a next period. Before the even counter 401 finishes counting, another odd parallel load signal starts the odd counter 402 and also counts from the beginning of a current period to the end of a next period. The combined output of both counters forming the leading edge of the timing generator is shown as the timing generator output (TG OUTPUT) line in FIG. 5.

Because the timing accuracy in an ATE system is critical to testing a device, it needs to be maintained carefully. Most of the ATE systems use integrated circuits or devices of a bipolar family in the timing subsystem 102. Consequently, the format and response subsystem 103 is also forced to use the bipolar family and thereafter. The bipolar family has better timing stability as compared to the CMOS family. However, CMOS has much, much higher integration as compared to the bipolar family. Therefore, CMOS test systems have a smaller size and lower power comsumption. Most of the ATE manufacturers use bipolar family for the timing circuitry and CMOS for the data circuitry as shown in FIG. 1. There are a few test system manufacturers that use special techniques to stabilize the timing for the CMOS family and use it for the timing subsystem.

From the above discussion, it is clear that each pin of a tester uses three timing generators. Each timing generator includes two timing markers, one for the leading edge and the other for the trailing edge. Each timing marker requires two counters (even and odd) in order to be programmed from the current cycle to the end of the next cycle. This means that each pin uses 12 counters for three timing generators. Each counter has a minimum of 10 to 14 bits. Thus, a lot of circuits and devices are used for the counters.

In addition to a large number of circuits and devices used by the timing generators, the formatter circuit also has to split up its even and odd storage elements in order to form the data with correct timing to work properly with the timing generator outputs as shown in FIG. 6. As an example, in the EVEN block, the parallel load signal starts the even counter. The leading edge of the even TG OUTPUT in FIG. 6 is programmed in the current cycle and the trailing edge is programmed into the beginning of the next cycle. As can be seen, the even TG OUTPUT overlaps the start pulse of the next cycle.

The vector memory data only comes every cycle as shown in FIG. 6. When the even TG OUTPUT has not yet completely formed the formatted waveform with the n+1 cycle memory data, n+2 cycle memory data have already replaced the n+1 cycle memory data. Therefore, the memory data for the n+1 cycle have to be held for two cycles as well as the n+2 cycle memory data as shown in FIG. 6. This requires two storage elements to store the memory data. The actual output waveform is shown at the center of FIG. 6. Therefore, the storage elements also double the consumption of circuits and devices in addition to the timing generator. If both the timing generator and formatter circuits use a bipolar family, the size of the test system is large and the power consumption is high. Special cooling may also be required.

Another drawback in a conventional ATE system is that it requires a dedicated deskew circuit to align the channels. There are test systems that have the feature of being able to program timing generator into more than one cycle, and add the deskew value into the programmed value to eliminate the deskew circuit. However, at high frequency testing (short period), the deskew value takes up the usable programming range that is offered to the user and makes the hardware design of the system more complicated.

For example, the deskew value is about 8 to 10 ns in general. If the period is 10 ns and the user programs a delay of 14 ns, adding 8 to 10 ns of deskew value to the programmed value would require 22 to 24 ns to be programmed. This requires that the hardware be capable of being programmed into the 3rd cycle, which means that an additional (3rd) counter needs to be added as well as a third storage element. The size and the cost of the system are significantly increased.

### SUMMARY OF THE INVENTION

This invention has been made to overcome the above mentioned drawbacks of a conventional ATE system. The primary object is to provide a new architecture for an ATE. Accordingly, a test system in a modularized form is provided in the invention so that each module can be implemented by a different family of devices such as bipolar or CMOS. The system comprises a vector memory subsystem, a coarse timing subsystem, a format and response subsystem, a timing refiner circuit, and a test head subsystem.

Another object of the invention is to provide a timing system having separate coarse and precise timing modules for an ATE system. The coarse timing module is a coarse timing subsystem that does not include a vernier circuit. Coarse timing works with the information from vector memory to form a waveform in a coarse timing manner. The precise timing module is a timing refiner circuit inserted after the format and response subsystem to re-synchronize, stabilize and adjust the waveform of the output of the format and response subsystem.

Because the coarse timing subsystem only provides a coarse timing signal that is synchronous to a system clock, CMOS family devices can be used. Subsequently, the format and response subsystem can also be changed to use CMOS family devices. The size and power consumption of the test system is significantly reduced.

It is a further object of the invention to provide a precise timing module having synchronization circuit for removing jitter produced by CMOS devices of the timing generator and formatter circuits. The timing refiner circuit of the system includes a flip-flop device to re-synchronize the jittery waveform and remove the jitter. Dependent on the requirement, the re-synchronization can be implemented using either a bipolar family circuit for better performance or a CMOS family for a lower cost test system.

It is also an object of the invention to provide a timing system that can simplify the design of the format and response system. According to the invention, the timing refiner circuit comprises a counter and/or shift register and vernier circuit in which the stabilized waveform triggers a counter or shift register before it goes into a vernier circuit. This arrangement simplifies the design of the format and response circuit and increases the reliability of the test system by putting the timing in a safe zone.

It is yet another object of the invention to provide a test system that does not require a deskew circuit. Because small counters or shift registers in the timing refiner circuit only deal with waveform timing alone, they can be delayed as many cycles as needed without worrying about carrying the data, the deskew value can be added to the programmed value of the counter without a complicated design. The deskew circuit used in a conventional system is therefore eliminated.

It is yet a further object of the invention to simplify the architecture of an ATE system by removing the formatter circuit and having an optional coarse timing subsystem. By having the timing generator output directly manipulate the timing using the output enable or chip select port of the memory devices in the vector memory subsystem, the formatter circuit can be eliminated. Furthermore, the counters or shift registers in the timing refiner circuit can be provided with enough programming range to even eliminate the coarse timing subsystem.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows the block diagram of a conventional ATE system.

FIG. 2 shows a timing marker used in the conventional timing subsystem of an ATE system.

FIG. 3 shows the timing diagram of the conventional timing marker.

FIG. 4 shows that two counters are required in the timing marker for a timing generator in the conventional timing subsystem.

FIG. 5 shows the timing diagram of a timing marker with two counters.

FIG. 6 illustrates that two storage elements are required in the formatter circuit of a conventional ATE system in order to hold the memory data in two consecutive cycles.

FIG. 7A shows the block diagram of an ATE system according to the present invention.

FIGS. 7B-7D show three different embodiments of the timing refiner circuit in FIG. 7A.

FIG. 8 shows the timing diagram of using a flip-flop device in the timing refiner circuit of this invention to remove jitter.

FIG. 9 illustrates how a flip-flop device removes jitter of a formatted waveform.

FIG. 10 shows the counter and/or shift register and vernier circuit of this invention and the timing diagram associated with the circuit.

FIG. 11 shows another architecture with an optional coarse timing subsystem for the ATE system of the present invention.

FIG. 12 shows that a memory device is used to generate formatted waveform according to the invention.

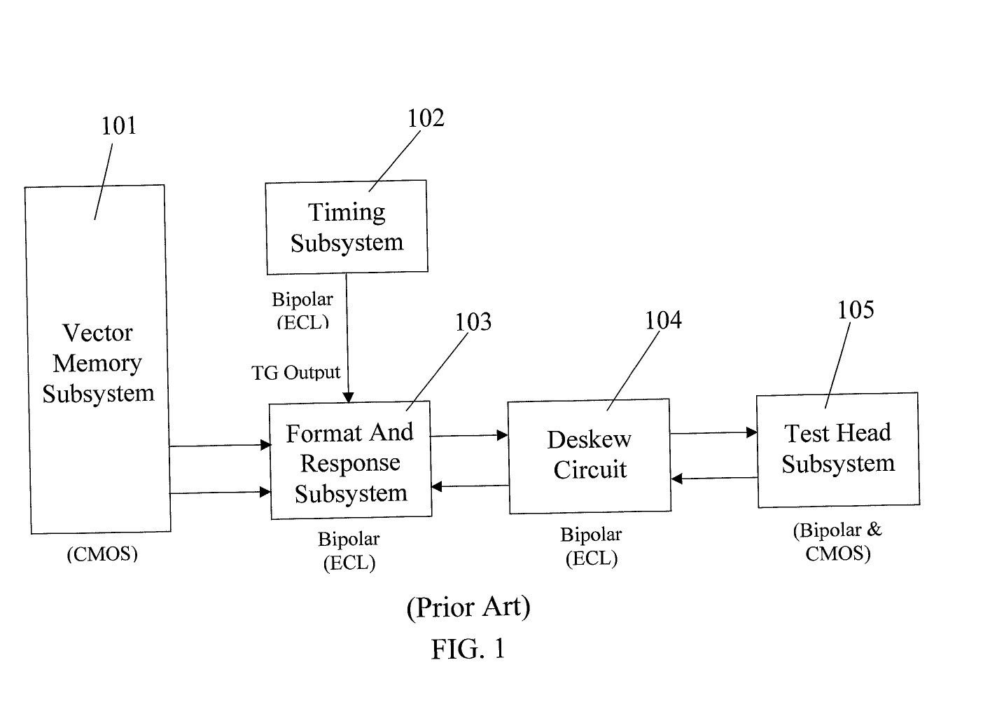

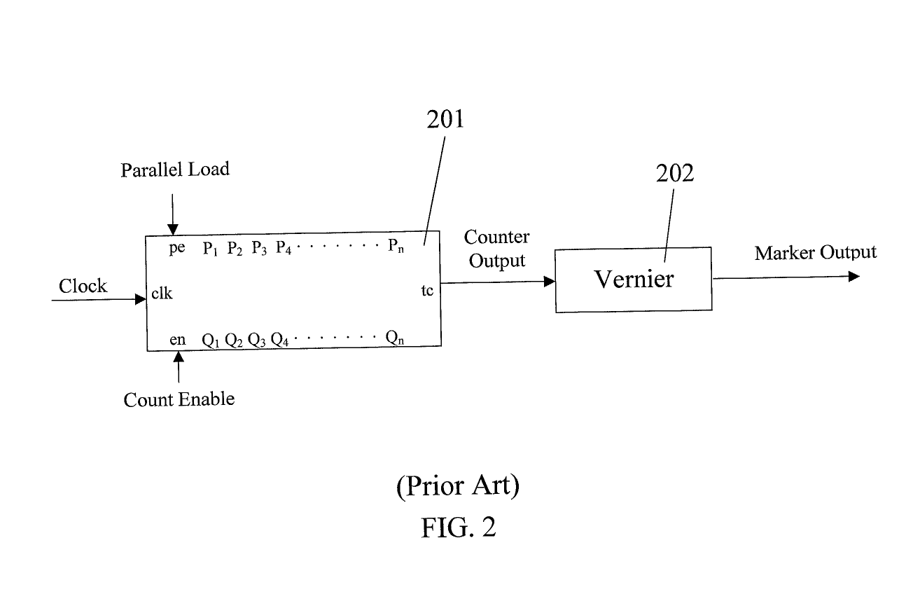

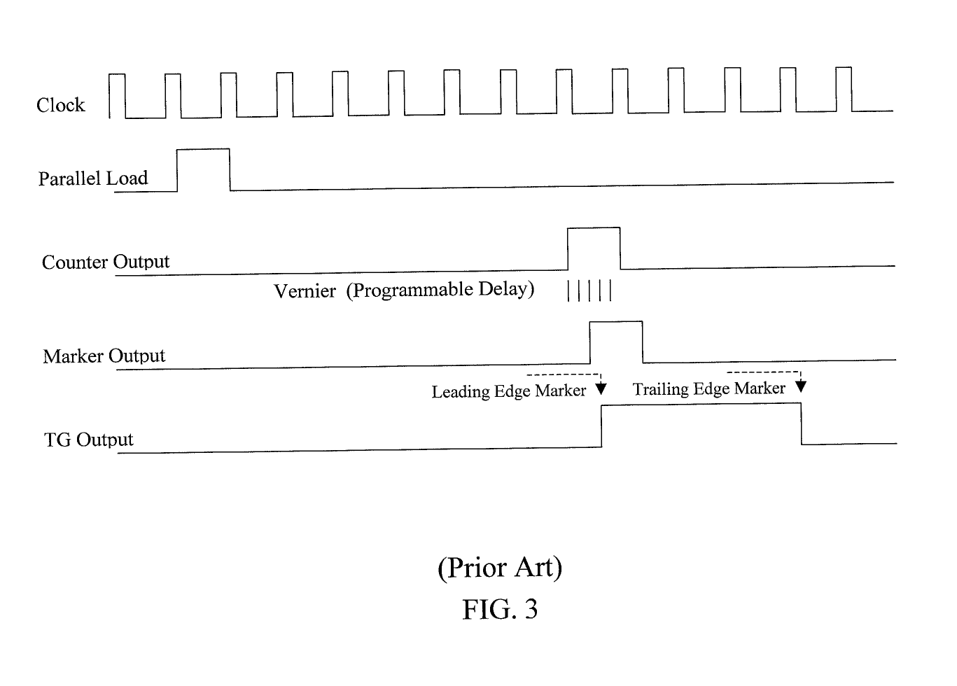

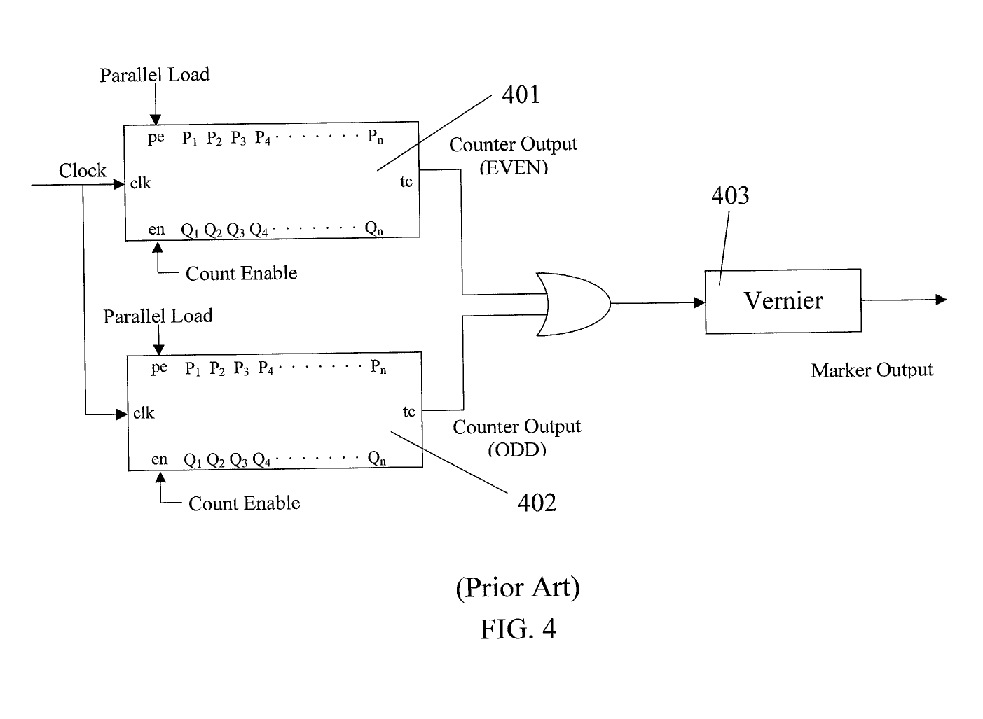

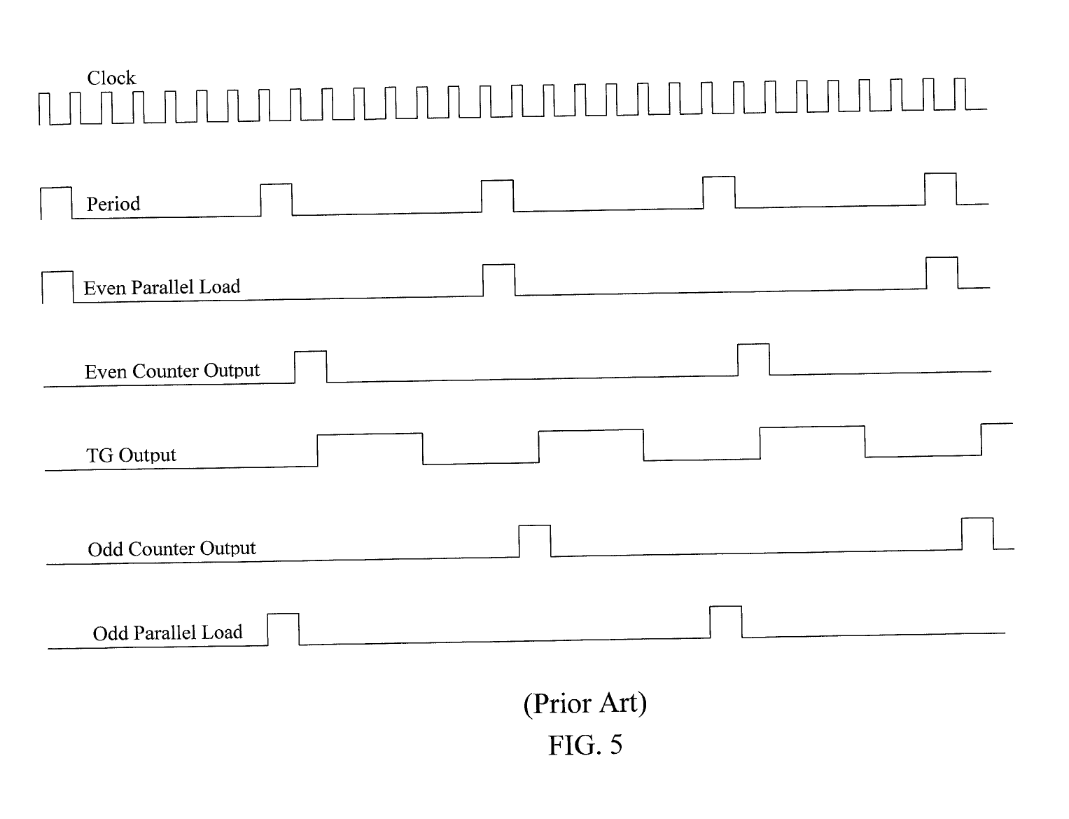

### DETAILED DESCRIPTION OF THE INVENTION

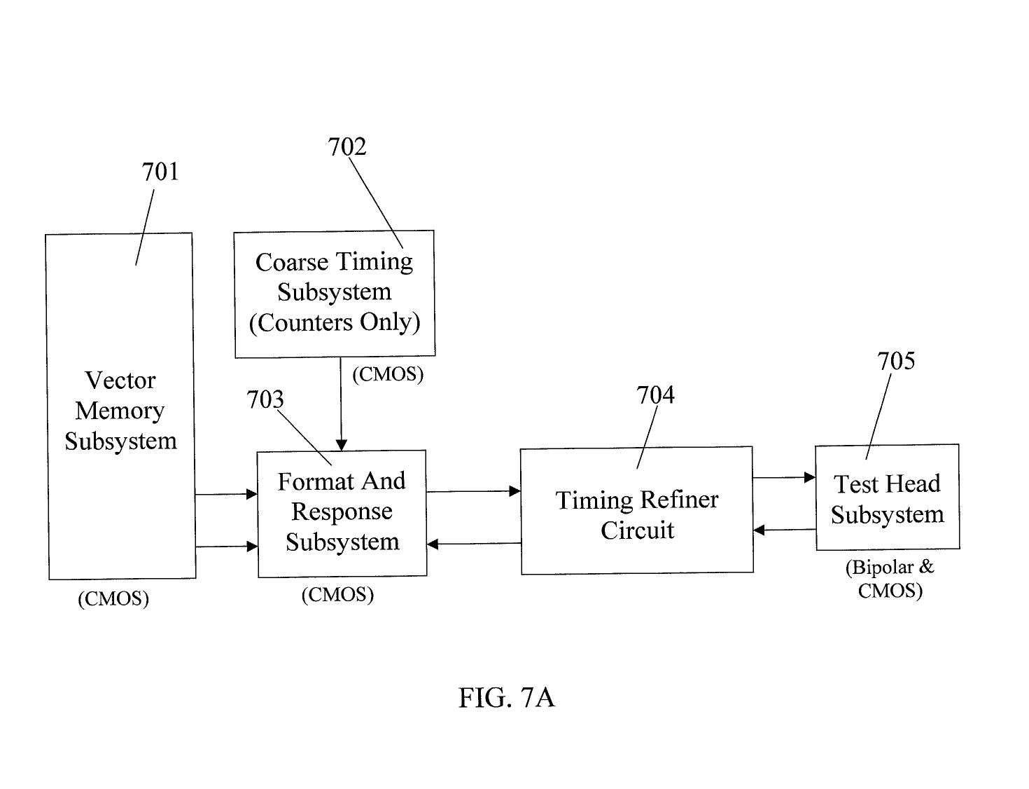

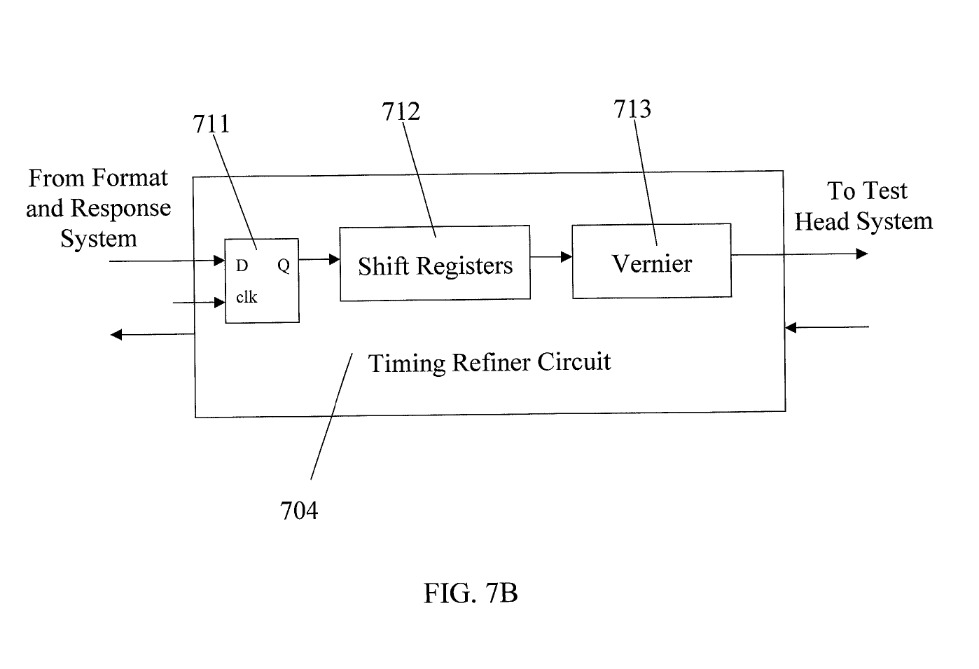

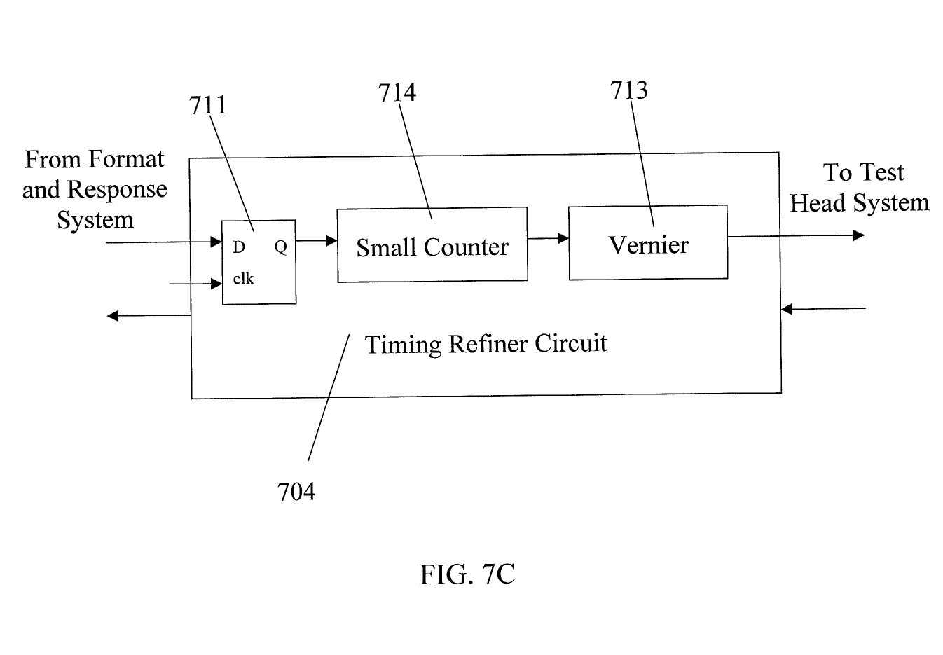

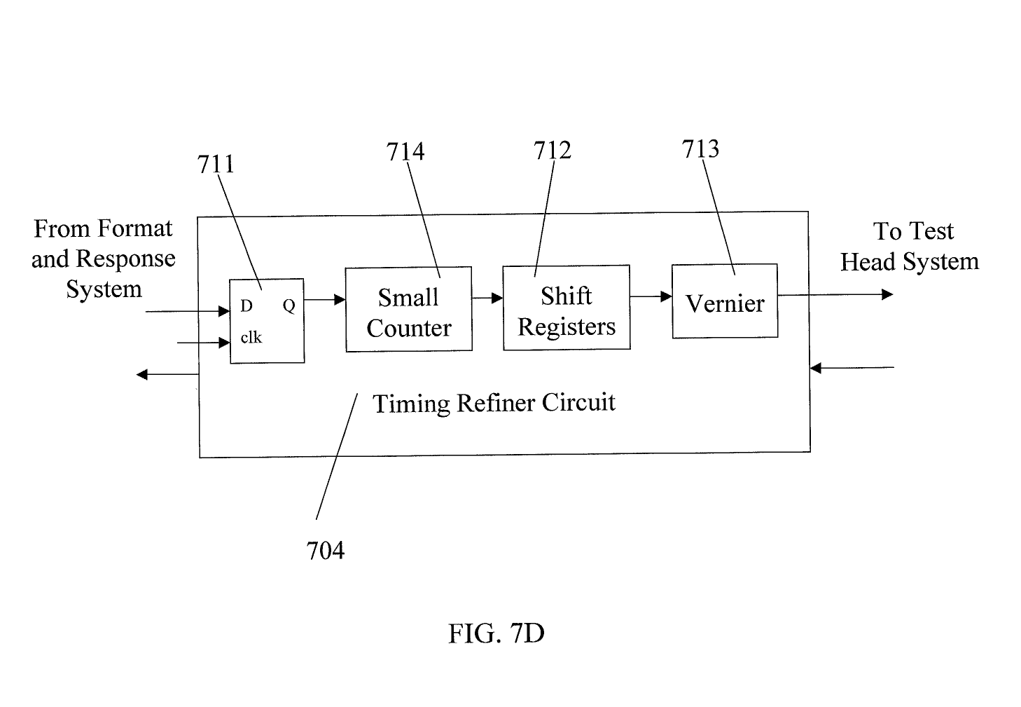

With reference to FIG. 7A, the block diagram of the ATE system according to this invention is illustrated. The system comprises a vector memory subsystem 701, a coarse timing subsystem 702, a format and response subsystem 703, a timing refiner circuit 704, and a test head subsystem 705. In contrast to a conventional ATE system, both coarse timing subsystem 702 and format and response subsystem 703 of this invention are implemented by CMOS devices rather than bipolar devices.

The vector memory subsystem 701 stores the information for stimulating and testing a device and comparing with test results. The coarse timing subsystem 702 does not include a vernier circuit used in the timing subsystem of a conventional ATE system. The format and response subsystem 703 combines the data from the vector memory 701 with coarse timing provided by the coarse timing subsystem 702 to form a waveform that may be jittered. The timing refiner circuit 704 refines the formatted waveform with precise timing and then sends it to the device. Each pin of the device is physically connected to a channel. The test head subsystem 705 is the interface mechanism which connects each channel to each pin of the device.

Instead of determining the precise timing to input the information and compare the output of the device, the coarse timing subsystem 702 only provides a coarse timing signal that is synchronous to a system clock. CMOS family devices are used for the coarse timing subsystem 702 and the format and response subsystem 703 to reduce the size and power consumption of the system. Because a vernier circuit has been removed from the timing subsystem 702, jitter may occur on the outputs of the coarse timing subsystem 702 as well as the formatted waveform output of the format and response subsystem 703.

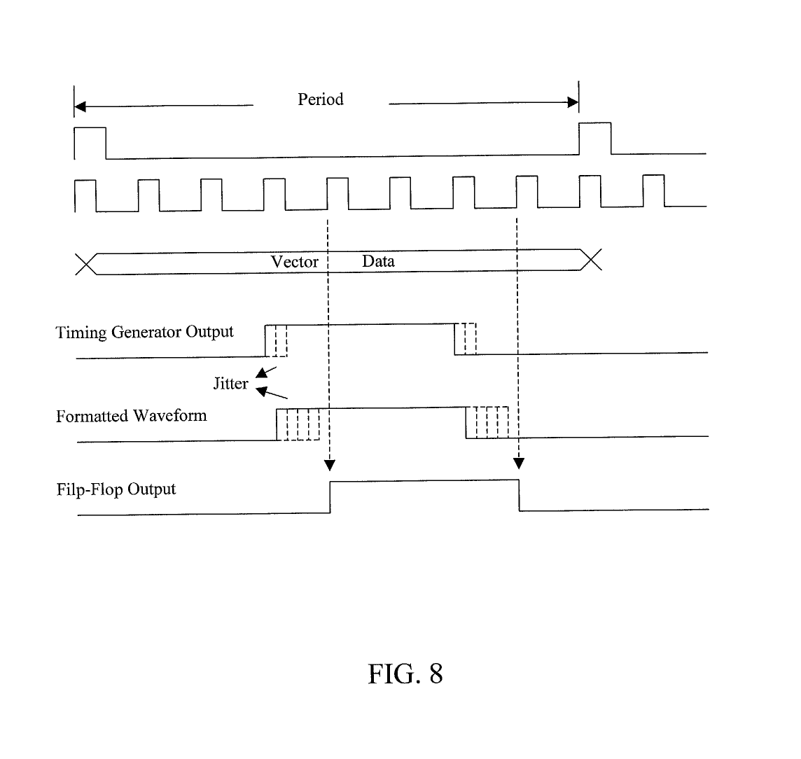

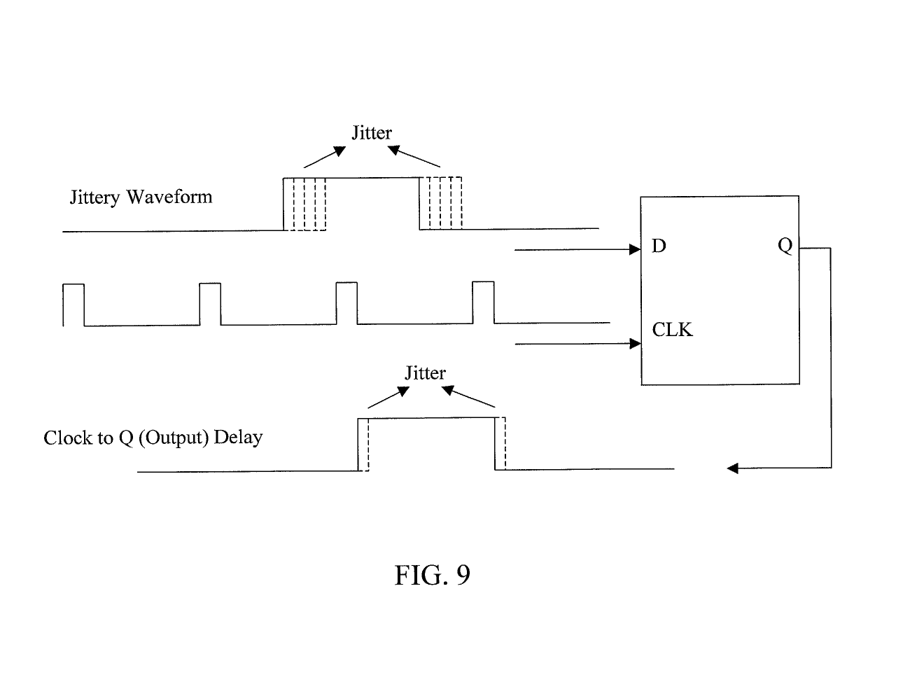

FIG. 8 illustrates the timing diagram for the ATE system of FIG. 7A. As can be seen, the jitter occurring at the timing generator output is further worsened by the format and response subsystem 703. To overcome the jitter problem, the present invention provides a timing refiner circuit 704 as shown in FIG. 7A. With reference to FIG. 7B, a flip-flop device 711 in the timing refiner circuit 704 is used to reproduce a more stable waveform illustrated in FIG. 8. The degree of stabilization of the waveform depends on the family of device that is used. FIG. 9 shows that if a more stable flip-flop is used, the jittery synchronous waveform that is the input to the flip-flop is stabilized after re-clocking and eliminating the jitter as a result.

As mentioned earlier, the coarse timing subsystem 702 does not include a vernier circuit. The present invention provides a counter and/or shift register and vernier circuit in the timing refiner circuit 704 to produce finer resolution for the timing after the formatted waveform has been stabilized. FIGS. 7B-7D show three different embodiments for the timing refiner circuit. In FIG. 7B, shift registers 712 and a vernier 713 are used. A small counter 714 replaces the shift register 712 in FIG. 7C. In FIG. 7D both a small counter 714 and shift registers 712 are used in the timing refiner circuit 704.

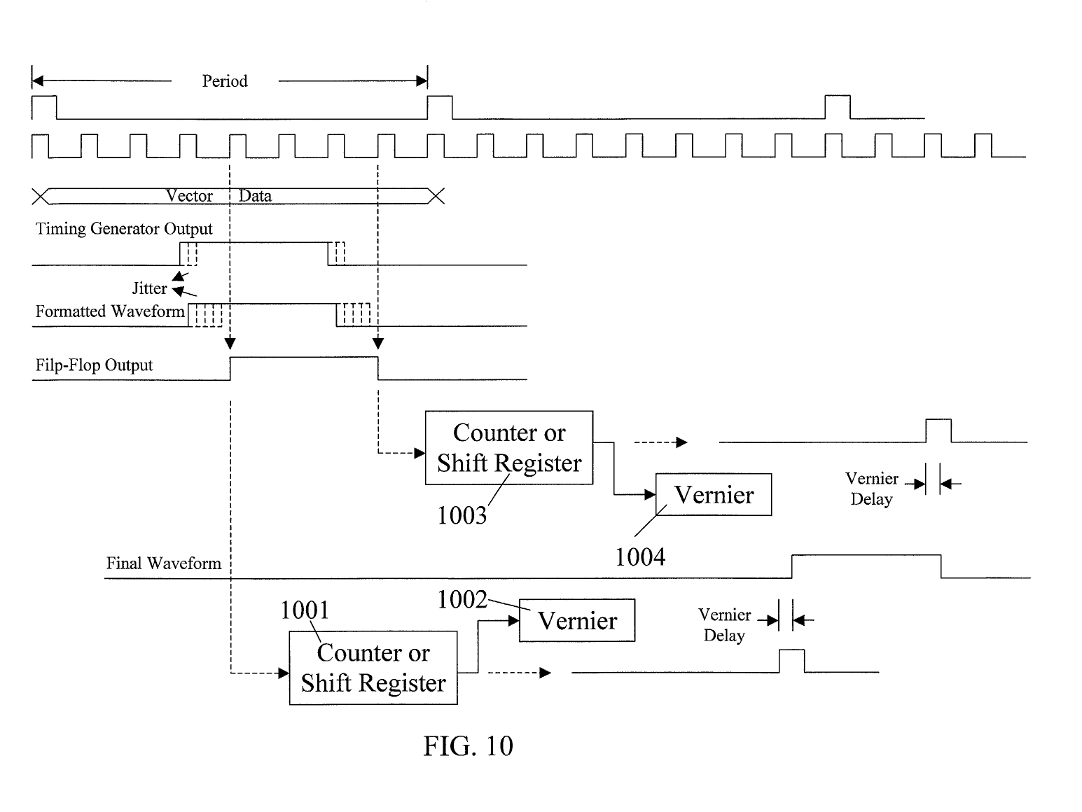

FIG. 10 shows more detail for the counter and/or shift register and vernier circuit. The leading edge of the flip-flop output triggers a small counter 1001 or shift register followed by a vernier 1002 to reproduce the leading edge of the final waveform with much finer resolution. Similarly, the trailing edge of the flip-flop output triggers a small counter 1003 or shift register followed by a vernier 1004 to reproduce the trailing edge of the final waveform with much finer resolution.

By having a counter and/or shift register and vernier circuit in the timing refiner circuit 704 has another advantage that the deskew subsystem used in a conventional test system can be eliminated. The deskew value can be added to the programmed value of the small counter or shift register together with the vernier. In addition to adding the deskew value, part of the pipe-line timing for a strobe can also be added to the programmed value of the small counters and/or shift registers. This makes calibration of the test system timing much easier.

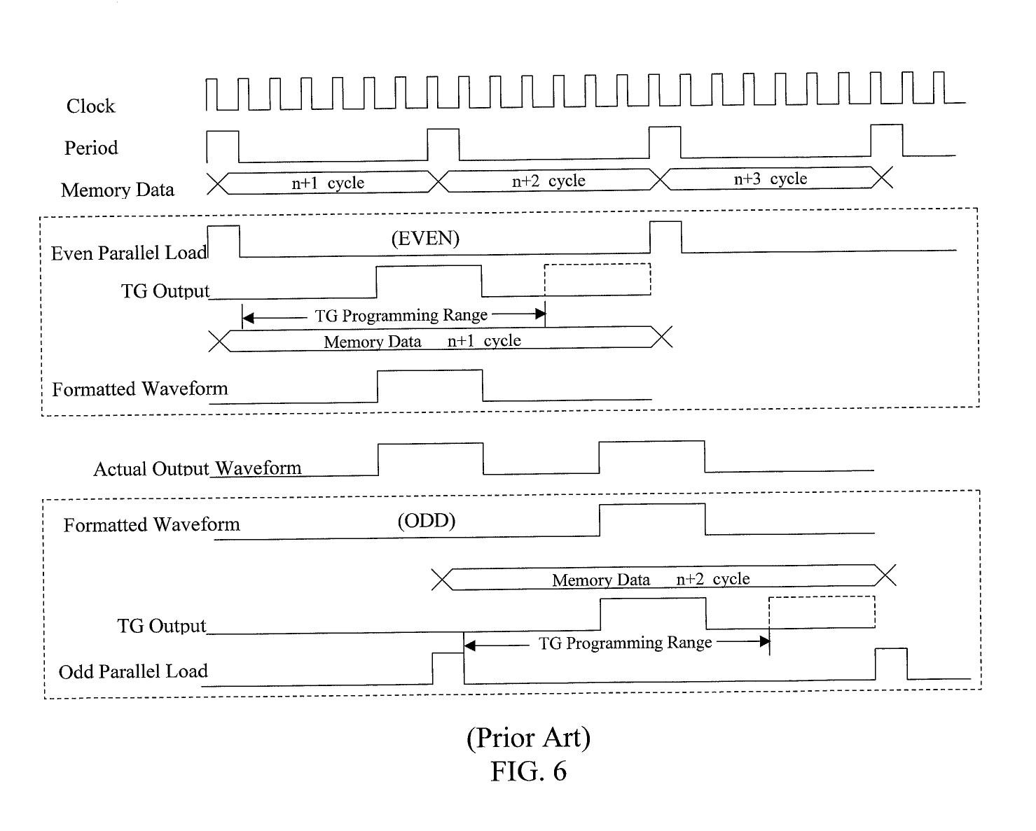

It is worth mentioning that the timing generator according to this invention is operated at a current cycle as shown in the timing diagram in FIG. 8. The reasons for having the small counters are to minimize the additional storage elements required in the conventional test system as illustrated in FIG. 6., to simplify the design of the format and response subsystem for only dealing with the timing and data in the current cycle at the very safe zone, and to eliminate the deskew circuit.

In the present invention, the jitter produced by the CMOS family can be eliminated by re-synchronizing the jittery signals with the system clock using either a bipolar family circuit for better performance or a CMOS family for a lower cost test system. This leaves the freedom for the manufacturer to decide what kind of family devices are used for the counter and/or shift register and vernier circuit in the timing refiner circuit 704 as shown in FIG. 7A.

Accordingly, this invention reduces at least half of silicon that is used in the timing generator and formatter circuits of a test system. It also simplifies the complex circuit and makes each subsystem of the test system into a modular form. Consequently, an ATE manufacturer has the freedom of using different families of devices, either bipolar or CMOS in each subsystem to achieve different performance benefits to capture the market.

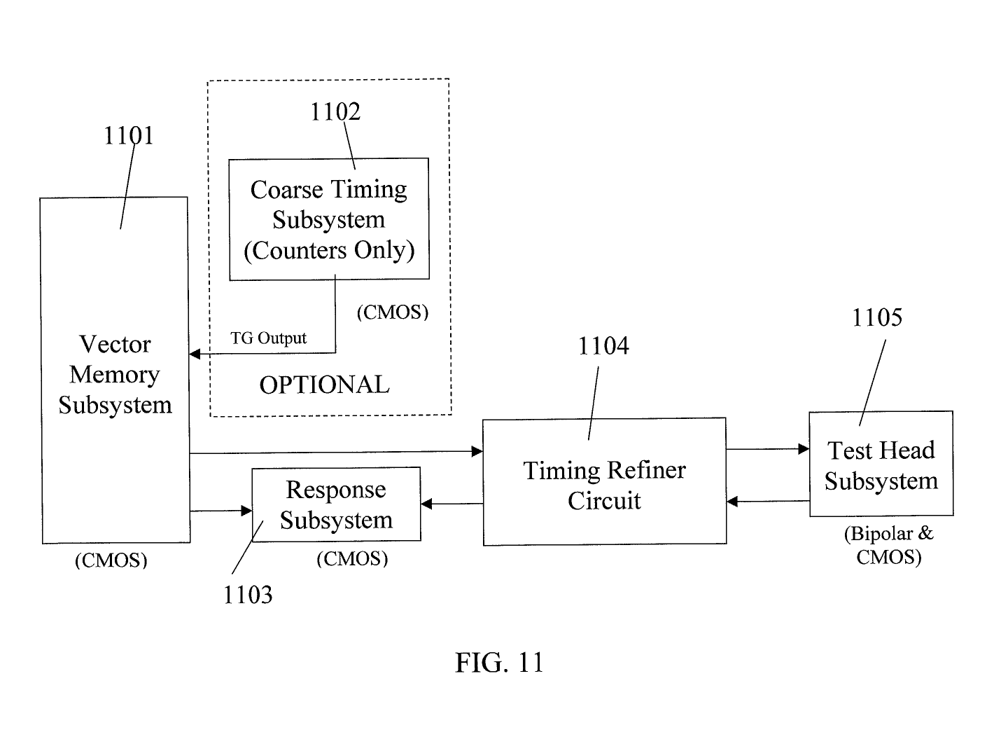

As a result of removing the vernier circuit from the timing subsystem of a conventional ATE system, another architecture that eliminates the formatter circuit is also made possible as shown in FIG. 11. The timing generator output from the coarse timing subsytem 1102 is sent to the vector memory subsystem 1101 to directly manipulate the timing by means of the output enable or chip select port of the memory devices in the vector memory subsystem 1101. The vector memory subsytem 1101 generates formatted waveform output and sends it directly to the timing refiner circuit 1104.

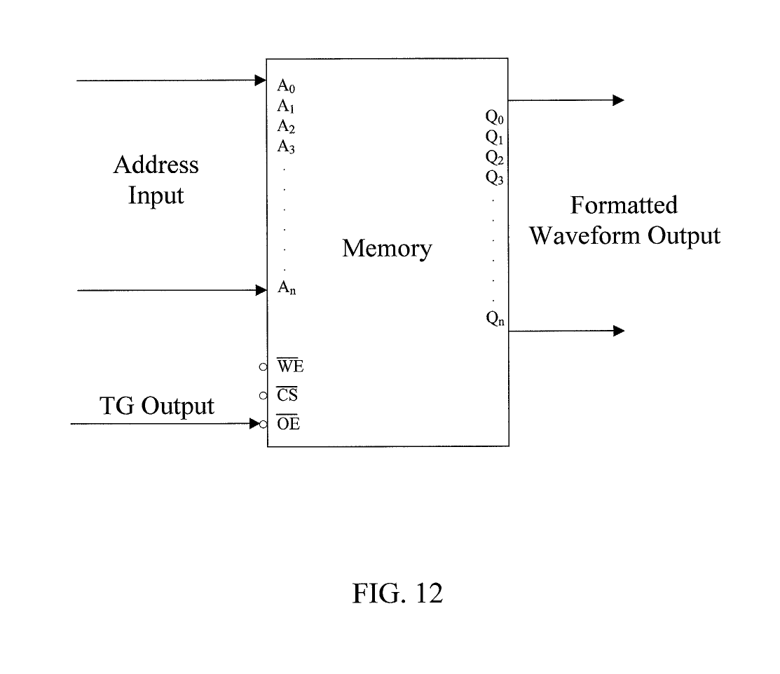

The memory that contains the data can serve as part of the formatter circuit as shown in FIG. 12. The response subsystem 1103, the timing refiner circuit 1104 and the test head subsystem 1105 remain similar to those described above and illustrated in FIG. 7A. If the counters or shift registers in the timing refiner circuit 1104 are provided with enough range, both the coarse timing subsystem and the format subsystem can be completely eliminated by further removing the optional coarse timing subsystem 1102 indicated in FIG. 11. In this case, part of the format functions is accomplished by manipulating the timing in the counter and/or shift register and vernier circuit of the timing refiner circuit 1104.

In summary, this invention has the following advantages:

1. The timing subsystem is divided into two modules. The first module only produces the coarse timing to work with the vector memory. Because it is only for coarse timing, fine accuracy is not necessary. This advantage allows the coarse timing subsystem as well as the format and response subsystem to use the highly integrated CMOS process. Only the second module deals with the fine timing.

2. Because the test system of this invention is in modular form, the coarse timing module produces waveforms together with the vector memory information. This process only takes place in the current cycle at the safe zone as shown in FIG. 8. After the memory data information already combines with the timing, the precise timing has to be dealt with the waveform only. The leading and trailing edges of the waveform can further be delayed by using small counters and/or shift registers to count into many cycles without worrying about the information.

3. The format and response circuit in the test system is simplified with the timing placed at the center of the period at very high speed. It improves the reliability of the design.

4. Because the small counters or shift registers only deal with timing alone, they can be delayed as many cycles as needed without worrying about carrying the data. The deskew value can be added into the programmed timing value without any restriction. The second module only deals with timing because the information already combines with the coarse timing in the first module. Therefore, there is no even/odd timing and even/odd storage elements.

5. In addition to adding the deskew value to the programmed value of the small counter and/or shift register, part of the pipe-line timing for the strobe can also be added. This makes the test system timing calibration much easier.

6. The format subsystem may be eliminated by manipulating the timing using the output enable or chip select port of the memory devices. Furthermore, the coarse timing subsystem may also be eliminated by providing enough range for the counters in the counter and/or shift register and vernier circuit to manipulate the timing.

With all these major advantages, the test system can be small in size because the majority of the components are CMOS. It also can preserve the bipolar stability for the timing because the final stage which requires only a small amount of devices can use bipolar components.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A tester for testing a device, comprising:
a vector memory subsystem storing information used for stimulating and testing a device and comparing test results;
a coarse timing subsystem generating a coarse timing signal;
a format and response subsystem receiving said information and said coarse timing signal, and generating a first formatted waveform with coarse timing;
a timing refiner circuit receiving said first formatted waveform, and generating a second formatted waveform with precise timing; and
a test head subsystem receiving said second formatted waveform;
wherein said test head subsystem sends said second formatted waveform to said device and returns test results through said timing refiner circuit to said format and response system.

2. The tester as claimed in claim 1, said timing refiner circuit including a flip-flop device for re-synchronizing said first formatted waveform and removing jitter from said first formatted waveform.

3. The tester as claimed in claim 2, said timing refiner circuit further including a counter and a vernier for generating said second formatted waveform with precise timing.

4. The tester as claimed in claim 2, said timing refiner circuit further including at least a shift register, and a vernier for generating said second formatted waveform with precise timing.

5. The tester as claimed in claim 2, said timing refiner circuit further including a counter, at least a shift register, and a vernier for generating said second formatted waveform with precise timing.

6. The tester as claimed in claim 2, said timing refiner circuit comprising a first counter or register coupled to a first vernier for triggering the leading edge of said second formatted waveform, and a second counter or register coupled with a second vernier for triggering the trailing edge of said second formatted waveform, wherein said first and second counters or registers are coupled to said flip-flop device.

7. The tester as claimed in claim 2, said timing refiner circuit having at least a programmed value, said programmed value being added with a deskew value used for aligning channels.

8. The tester as claimed in claim 2, said timing refiner circuit having at least a programmed value, said programmed value being added with a pipe-line timing value.

9. The tester as claimed in claim 1, said vector memory subsystem, said coarse timing subsystem, and said format and response system being implemented by CMOS devices.

10. A tester for testing a device, comprising:
a vector memory subsystem storing information used for stimulating and testing a device and comparing test results, said vector memory subsystem outputting a first formatted waveform with coarse timing based on said information;
a timing refiner circuit receiving said first formatted waveform and generating a second formatted waveform with precise timing;
a response subsystem receiving said information from said vector memory subsystem; and
a test head subsystem receiving said second formatted waveform;
wherein said test head subsystem sends said second formatted waveform to said device and returns test results through said timing refiner circuit to said response system.

11. The tester as claimed in claim 10, said timing refiner circuit including a flip-flop device for re-synchronizing said first formatted waveform and removing jitter from said first formatted waveform.

12. The tester as claimed in claim 11, said timing refiner circuit further including a counter and a vernier for generating said second formatted waveform with precise timing.

13. The tester as claimed in claim 11, said timing refiner circuit further including at least a shift register, and a vernier for generating said second formatted waveform with precise timing.

14. The tester as claimed in claim 11, said timing refiner circuit further including a counter, at least a shift register, and a vernier for generating said second formatted waveform with precise timing.

15. The tester as claimed in claim 11, said timing refiner circuit comprising a first counter or register coupled to a first vernier for triggering the leading edge of said second formatted waveform, and a second counter or register coupled with a second vernier for triggering the trailing edge of said second formatted waveform, wherein said first and second counters or registers are coupled to said flip-flop device.

16. The tester as claimed in claim 11, said timing refiner circuit having at least a programmed value, said programmed value being added with a deskew value used for aligning channels.

17. The tester as claimed in claim 11, said timing refiner circuit having at least a programmed value, said programmed value being added with a pipe-line timing value.

18. The tester as claimed in claim 10, said vector memory subsystem, and said response system being implemented by CMOS devices.

19. The tester as claimed in claim 10, further comprising a coarse timing subsystem generating a coarse timing signal and sending said coarse timing signal to said vector memory subsystem for generating said first formatted waveform with coarse timing.

20. The tester as claimed in claim 19, said timing refiner circuit including a flip-flop device for re-synchronizing said first formatted waveform and removing jitter from said first formatted waveform.

21. The tester as claimed in claim 20, said timing refiner circuit further including a counter and a vernier for generating said second formatted waveform with precise timing.

22. The tester as claimed in claim 20, said timing refiner circuit further including at least a shift register, and a vernier for generating said second formatted waveform with precise timing.

23. The tester as claimed in claim 20, said timing refiner circuit further including a counter, at least a shift register, and a vernier for generating said second formatted waveform with precise timing.

24. The tester as claimed in claim 20, said timing refiner circuit comprising a first counter or register coupled to a first vernier for triggering the leading edge of said second formatted waveform, and a second counter or register coupled with a second vernier for triggering the trailing edge of said second formatted waveform, wherein said first and second counters or registers are coupled to said flip-flop device.

25. The tester as claimed in claim 20, said timing refiner circuit having at least a programmed value, said programmed value being added with a deskew value used for aligning channels.

26. The tester as claimed in claim 20, said timing refiner circuit having at least a programmed value, said programmed value being added with a pipe-line timing value.
